(19) United States
(12) Patent Application Publication
(10) Pub. No.: US 2003/0218478 A1
(43) Pub. Date: Nov. 27, 2003

(54) Regulation of crowbar current in circuits employing footswitches/headswitches

(76) Inventors: Mehdi Hamidi Sani, San Diego, CA (US); Gregory A. Uvieghara, San Diego, CA (US); John Dejaco, Chula Vista, CA (US)

Correspondence Address: Qualcomm Incorporated, Patents Department, 5775 Morehouse Drive, San Diego, CA, 92121-1714, US

(21) Appl. No.: 10/155,956

(22) Filed: May 24, 2002

(51) Int. Cl. H03K 19/003

(52) U.S. Cl. 326/33

(57) ABSTRACT

Pullup and/or pulldown transistors are electrically connected to the output of MTCMOS logic gates. The use of a pullup transistor pulls up the output to a known, non-floating voltage level when the circuit enters a sleep mode (e.g. the high voltage threshold headswitch and/or footswitch are de-asserted) eliminating crowbar current from being drawn by connected circuits having neither footswitches nor headswitches. Likewise, when a pulldown transistor is electrically connected to the output of the MTCMOS logic gates, the output is pulled down to ground, or other reference level, when the circuit is in a sleep mode. As a result of the addition of a pullup or pulldown transistor on the output of the logic gates, the output is pulled to a known, non-floating voltage level, and the drawing of crowbar current from components that are electrically connected to the output of the logic gates is prevented.

### BACKGROUND

1. Field

The invention relates to CMOS circuits. More specifically, the invention relates to regulation of crowbar current in CMOS circuits having footswitches and/or headswitches.

2. Description

In order to achieve suitable battery life and achieve miniaturization of portable electronic devices, the use of power saving techniques are often employed. Because power dissipation in digital circuits, and more specifically in digital CMOS circuits, is approximately proportional to the square of the supply voltage, the most effective way to achieve low-power performance is to scale the supply voltage. However, in order to keep the propagation delay constant, the threshold voltage of the devices must also be proportionally reduced.

Unfortunately, the reduction in threshold voltage may cause a rapid increase in stand-by current due to changes in the subthreshold leakage current. In other words, leakage current, which is, in general, the current that flows through an “off” transistor, increases exponentially as the threshold voltage of a device is reduced. This condition is described in greater detail in Mutoh, S., et al., “1-V power supply high-speed digital circuit technology with multi-threshold-voltage CMOS,” IEEE Journal of Solid-State Circuits, Vol. 30, No. 8, p. 847-854 (August 1995).

Therefore, devices such as cell phones that remain for extended periods in a low power, or stand-by mode, have increased leakage current, and, thus increased drain on the battery power during stand-by mode.

FIG. 1 is a schematic illustrating an exemplary prior art Multi-Threshold CMOS (“MTCMOS”) circuit configured to reduce the amount of leakage current, especially in circuits where the supply voltage, and, thus the threshold voltages of the logic gates, have been lowered. Logic gates may comprise any type of logic gates in any configuration. For example, logic gates may comprise a single CMOS inverter. Logic gates may also comprise a combination of any number and combination of low voltage threshold AND, NAND, OR, NOR, XOR, or other logic gates. The exemplary MTCMOS circuit 100 comprises one or more low voltage threshold (“LVT”) logic gates 110 electrically connected to a virtual power VDDV 102 and a virtual ground GNDV 104, instead of the actual power VDD 106 and actual ground GND 108. In one embodiment, VDD 106 and GND 108 are two terminals on a battery. For example, in a cellular phone, the two terminals may have a voltage difference of between 0.5 and 2.0 volts.

The VDD 106 is electrically connected to a high voltage threshold headswitch transistor (“headswitch”) 112, which is controlled by a high asserted sleep signal SL 116. The output of the headswitch 112, and thus the voltage on VDDV 102, is substantially equal to VDD 106 when SL 116 is de-asserted (e.g. SL 116 is low). Similarly, The GND 108 is electrically connected to a high voltage threshold footswitch transistor (“footswitch”) 114, which is controlled by a low asserted sleep signal /SL 120. The output of the footswitch 114, and thus the voltage on GNDV 104, is substantially equal to GND 108 when /SL 120 is de-asserted (e.g. /SL 120 is high). In one design, /SL 120 and SL 116 are derived from a common signal, and, thus are asserted simultaneously. As such, the headswitch 112 and footswitch 114 turn on and off at substantially the same times.

During a sleep or stand-by mode, the sleep signals SL 116 and /SL 120 are de-asserted, causing the headswitch 112 and the footswitch 114 to turn off. Because the headswitch and footswitch have a high threshold voltage, the amount of leakage current drawn from VDD 106 is reduced. In contrast, if the headswitch and footswitch are not used, during a sleep mode the LVT logic gates 110 are electrically connected to VDD 106 and GND 108. Thus, because the LVT logic gates 110 are relatively leaky, the LVT logic gates 110 drain leakage current from the VDD 106.

Likewise, during an active mode, the sleep signals SL 116 and /SL 120 are asserted causing the headswitch 112 and the footswitch 114 to turn on so as to supply VDDV 102 and GNDV 104 to the logic gates 110. Therefore, during the active mode, the logic gates are powered by substantially the same voltage as if they were directly connected to VDD 106 and GND 108. Thus, MTCMOS circuit techniques allow the threshold voltage of the LVT logic gates 110 to be lowered while reducing the amount of leakage current during sleep modes.

Unfortunately, even when leakage current is minimized using the MTCMOS techniques discussed above, power may still be lost due to crowbar current. Crowbar current, in general, is caused during a transition when both the P-channel and N-channel transistors are partially “on.” Thus, when a CMOS inverter, for example, is transitioning between logic states, both PMOS and NMOS transistors are conducting for a brief period of time and a small current flows from the VDD voltage to the ground through the transistors. This current flow is commonly known in the industry as crowbar current.

Crowbar current may increase over time relative to the frequency of logic state transitions. As crowbar current increases, other undesirable effects, such as voltage spikes, electromigration, joule heating, and voltage supply ringing may also occur. Thus, crowbar current tends to degrade the performance of high speed integrated circuits, such as an Application Specific Integrated Circuit (ASIC), processor, programmable logic device, or memory, and leads to increased power loss for a particular device.

While MTCMOS techniques may significantly reduce the amount of leakage current in a CMOS circuit, crowbar current still exists. Thus, with respect to FIG. 1, any logic gates connected to the output 118 may draw a crowbar current when the circuit 100 is in a sleep mode. In particular, the output of the LVT logic gates 110 may float and allow circuits linked to the output 118 to draw a crowbar current.

A system and method for reducing crowbar current in MTCMOS circuits is desired.

### SUMMARY

The above mentioned problems are addressed by adding a pullup or pulldown transistor to the output of the MTCMOS logic gates.

The use of a pullup transistor, for example, pulls up the output to a known, non-floating level when the circuit enters a sleep mode (e.g. the high voltage threshold headswitch and/or footswitch are de-asserted). This prevents crowbar current from being drawn through the output of the logic gates by connected circuits. In particular, this eliminates crowbar current from being drawn by connected circuits having neither footswitches nor headswitches.

Likewise, when a pulldown transistor is electrically connected to the output of the MTCMOS logic gates, the output is pulled down to ground, or other reference level, when the circuit is in a sleep mode.

As a result of the addition of a pullup or pulldown transistor on the output of the logic gates, the output is pulled to a known, non-floating level, and components that are electrically connected to the output of the logic gates are prevented from drawing crowbar current.

The use of pullup or pulldown transistors on the output of logic gates may also aid in debugging and testing circuits. For example, when a particular logic gate is in a sleep mode the pullup or pulldown transistor ensures that the output is pulled to a known, non-floating level. Consequently, in a circuit comprising multiple logic gates employing footswitch and/or headswitches, the use of pullup or pulldown transistors on the outputs of the logic gates ensures that no nodes are indeterminate in the circuit when the circuit is in a sleep mode.

It will be appreciated that a MTCMOS circuit designed in accordance with the invention may be used in a device such as a mobile phone, pager, personal digital assistant, notebook computer, or any other electronic device.

These and other objects and features of the invention will become more fully apparent from the following description and appended claims taken in conjunction with the following drawings, where like reference numbers indicate identical or functionally similar elements.

### BRIEF DESCRIPTION OF THE DRAWINGS

FIG. 1 is a schematic illustrating an exemplary prior art MTCMOS circuit.

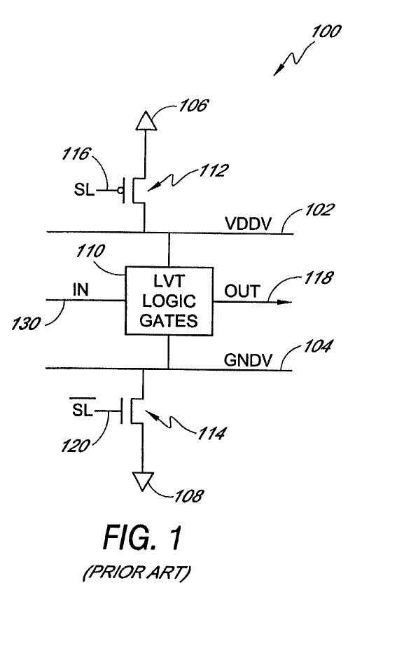

FIG. 2 is a schematic illustrating a logic gate powered via a headswitch and footswitch and having an output electrically connected to a pullup transistor.

FIG. 3 is a schematic illustrating a logic gate grounded via a footswitch and having an output electrically connected to a pullup transistor.

FIG. 4 is a schematic illustrating a CMOS inverter grounded via a footswitch and having an output electrically connected to a pullup transistor.

FIG. 5 is a schematic illustrating a logic gate powered via a headswitch and having an output electrically connected to a pulldown transistor.

FIG. 6 is a schematic illustrating a CMOS inverter powered via a headswitch and having an output electrically connected to a pulldown transistor.

### DETAILED DESCRIPTION

The following presents a detailed description of various embodiments. However, the invention can be embodied in a multitude of different ways as defined and covered by the claims. The invention is more general than the embodiments that are explicitly described, and is not limited by the specific embodiment, but rather is defined by the appended claims.

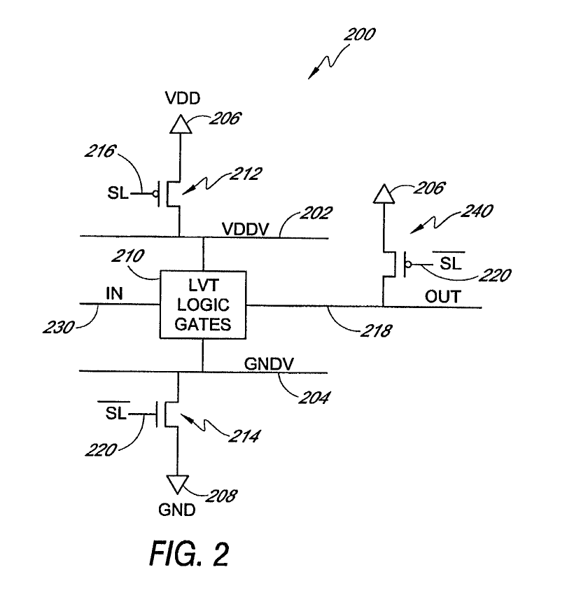

FIG. 2 is a schematic illustrating a logic gate 210 powered via a headswitch 212 and footswitch 214 and having an output 218 electrically connected to a pullup transistor 240. Headswitch 212 comprises a high voltage threshold PMOS transistor with its gate terminal electrically connected to a high asserted sleep signal SL 216. As is well known in the electrical arts, a PMOS transistor turns on, i.e. conducts current from the source to the drain, when the voltage on the gate is low, or below a threshold voltage. Thus, when SL 216 is low, the headswitch 212 is on, and VDDV 202 is electrically connected to VDD 206. Likewise, when SL 216 is high, the headswitch 212 is off, and the VDDV 202 is isolated from VDD 206.

The footswitch 214 of circuit 200 comprises a high voltage threshold NMOS transistor with its gate terminal electrically connected to a low asserted sleep signal /SL 220. A NMOS transistor turns on, i.e. conducts current from the source to the drain, when the voltage on the gate terminal is high, e.g. above a threshold voltage. Thus, when /SL 220 is high, the footswitch 214 is on, and GNDV 204 is electrically connected to GND 208. Likewise, when /SL 220 is low the footswitch 214 is off and the GNDV 204 is isolated from GND 208. Therefore, the sleep signal /SL 220 provides one means for activating and deactivating the footswitch 214 electrically connected to the logic gates 210.

Furthermore, the footswitch 214 provides one means for isolating the LVT logic gates 210 from the reference voltage, which, in this example, is GND 208. Because /SL 220 and SL 216 are the inverse of one another, in the embodiment of FIG. 2 both the headswitch 212 and footswitch 214 turn off and on at substantially the same times. More specifically, when SL 216 changes from high to low the headswitch 212 turns on, thus electrically connecting the VDDV 202 to VDD 206 and, at the same time, /SL 220 changes from low to high causing footswitch 214 to turn on, thus electrically connecting the GNDV 204 with GND 208. In this way, when SL 216 is asserted (i.e. /SL 220 goes low and SL 216 goes high) the VDD 206 and GND 208 signals are isolated from the LVT logic gates 210 and the logic gates are thereby placed in a sleep mode.

As mentioned above, depending on the state of the logic gate output 218 when /SL 220 is de-asserted, the output 218 may float during the sleep mode. However, in circuit 200 this problem is rectified through the use of the pullup transistor 240. In the embodiment of circuit 200, the pullup transistor 240 comprises a PMOS transistor with its gate electrically connected to /SL 220. Because the pullup transistor 240 is a PMOS type transistor that is driven by the low asserted sleep signal /SL 220, the pullup transistor 240 is active when the headswitch 212 and footswitch 214 are inactive (LVT logic gates 210 are in a sleep mode). Specifically, when SL 216 is asserted (e.g. /SL 220 is low) the pullup transistor 240 is turned on so that current flows between it's source and drain, which are connected to VDD 206 and output 218. As a result, the voltage level on output 218 is pulled up to the level of VDD 206 and prevented from floating. Accordingly, the sleep signal /SL 220 provides one means for activating the pullup transistor so that the voltage level on the output 218 is adjusted to a known voltage level. Furthermore, the pullup transistor provides one means for adjusting a voltage level on the output 218 to a known voltage level. With the addition of pullup transistor 240 to stabilize the voltage on output 218, another gate or device may be connected to output 218 without drawing crowbar current from the output 218.

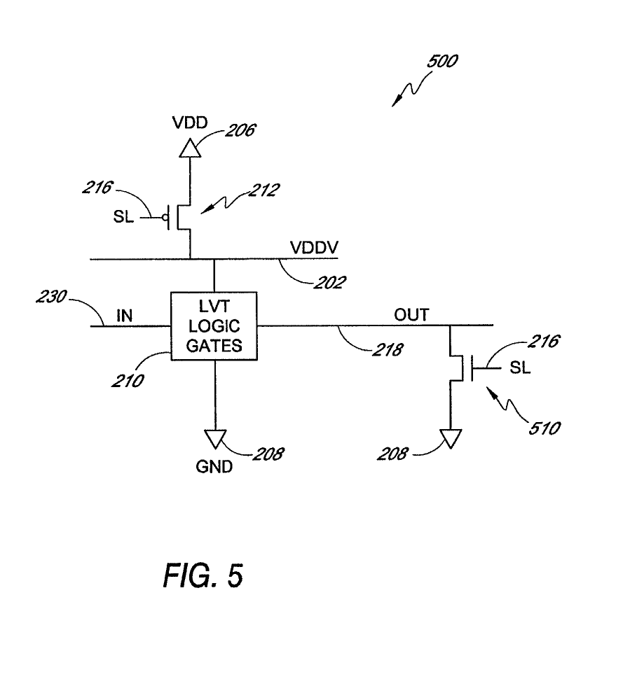

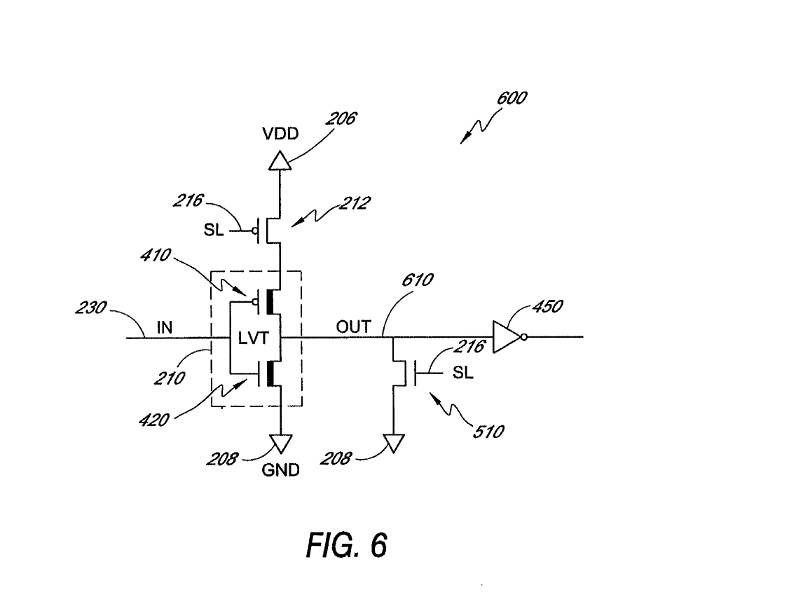

In other embodiments, the output 218 may be prevented from floating through the use of a pulldown transistor in place of pullup transistor 240 (See FIGS. 5 and 6). In this case, the output 218 is pulled to ground, or other reference voltage, when the LVT logic gates 210 are in a sleep mode. Thus, the pulldown transistor provides another means for adjusting a voltage level on the output 218 to a known voltage level.

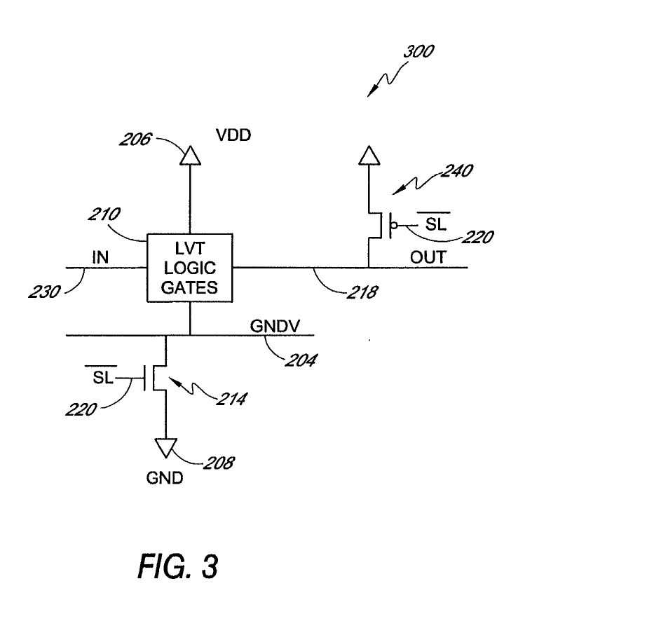

FIG. 3 is a schematic illustrating LVT logic gates 210 grounded via a footswitch 214 and having an output electrically connected to the pullup transistor 240. As shown in FIG. 3, the circuit 300 uses a NMOS footswitch 214, but not a headswitch. As such, the LVT logic gates 210 draw voltage directly from VDD 206, and a reference voltage from GND 208 via footswitch 214. However, similar to the circuits 100 and 200 with both a headswitch and footswitch, when SL 216 is asserted (/SL 220 is low), the logic gates lack a complete conduction path, and, thus, the drain of leakage current from VDD 206 by the LVT logic gates 210 is substantially eliminated. In addition, because NMOS transistors are typically faster and smaller than PMOS transistors, circuits having only a footswitch 214 typically have shorter propagation delays and require less physical circuit area.

Circuit 300 also includes a PMOS pullup transistor 240 with its gate terminal electrically connected to /SL 220. As discussed above with respect to FIG. 2, the pullup transistor 240 pulls the output 218 to VDD 206 when SL 216 is asserted. Thus, when the circuit is in a sleep mode the output 218 is prevented from floating.

In sum, the embodiment of FIG. 3 may be advantageous over a standard MTCMOS circuit, such as circuit 100, for example, in several respects. First, circuit 300 does not have a headswitch and therefore requires less circuit area. Second, by using only a NMOS footswitch 214, and not a PMOS headswitch 212, the circuit 300 may switch between sleep and active mode more rapidly as SL 216 is asserted and de-asserted. Finally, pullup transistor 240 ensures that output 218 does not float when /SL 220 is asserted and the circuit 300 is in a sleep mode, thus preventing crowbar current from being drawn by components connected to output 218.

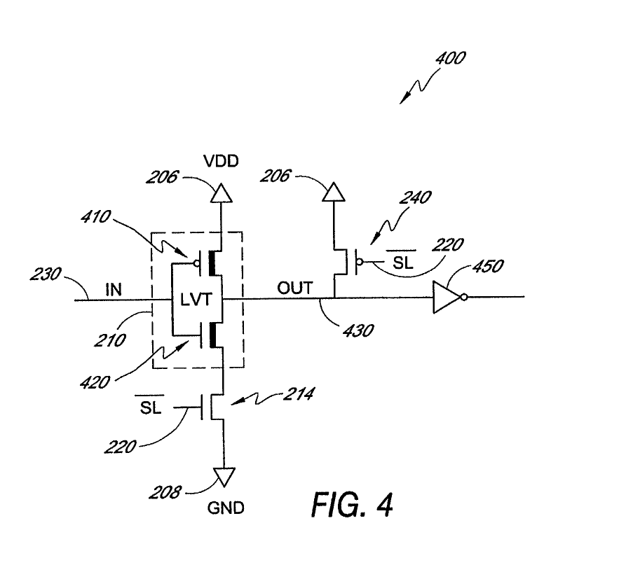

FIG. 4 is a schematic illustrating a CMOS inverter grounded via the footswitch 214 and having an output electrically connected to the pullup transistor 240. As shown in FIG. 4, LVT logic gates 210 comprise a CMOS inverter. In this embodiment, the CMOS inverter comprises a LVT PMOS transistor 410 and a LVT NMOS transistor 420 which both receive a single input signal 230. As such, when the LVT PMOS transistor 410 is on, the LVT NMOS transistor 420 is off, and vice versa. One output terminal of each of the LVT PMOS and NMOS transistors 410 and 420 are electrically connected to provide an output 430. The LVT PMOS transistor 410 is additionally electrically connected to a voltage source VDD 206 such that when the LVT PMOS transistor 410 is turned on by a low input 230, the output 430 is substantially equal to VDD 206. Likewise, the LVT NMOS transistor 420 is electrically connected to the reference signal GND 208 via footswitch 214. Thus, when the circuit 400 is in an active mode (SL is de-asserted) and the LVT NMOS transistor 420 is turned on by a high input 230, the output 430 is substantially equal to GND 208. Similarly, when the input 230 is low, the LVT PMOS transistor 410 creates a conduction path between the VDD 206 and the output 430. Also, when the input 230 is high, the LVT NMOS transistor 420 creates a conduction path between the GND 208 and the output 430.

As noted above, the LVT logic gates 210 are electrically connected to the footswitch 214 for switching the logic gates between active and sleep modes. In brief, when SL 216 is asserted, /SL 220 is low, the footswitch is off, and the logic gates are in the sleep mode. Conversely, when SL 216 is de-asserted, /SL 220 is high, the footswitch is on, and the LVT logic gates 210 are in the active mode. Again, the use of only a footswitch (and not a headswitch) may provide improved switching speed and require decreased circuit area.

The output 430, which is the inverse of input 230, is additionally electrically connected to the pullup transistor 240 to prevent the output 430 from floating when the logic gates are in the sleep mode. The operation of the pullup transistor 240 is the same as described above with respect to FIG. 3. In brief, when SL 216 is asserted (/SL 220 is low) the logic gates enter a sleep mode and the pullup transistor 240 turns on, thus pulling up the output 430 to VDD 206. Because the output 430 is prevented from floating during the sleep mode, additional logic gates, such as an inverter 450, for example, may be electrically connected to the output 430 without the risk of unwanted crowbar current flowing through the inverter 450.

FIG. 5 is a schematic of a circuit 500 illustrating LVT logic gates 210 powered by VDD 206 via headswitch 212 and connected directly to reference signal GND 208. As shown in FIG. 5, the circuit 500 uses the headswitch 212, but not a footswitch. As such, the LVT logic gates 210 draw voltage from VDD 206 via headswitch 212. Similar to the circuits 100 and 200 with both a headswitch and footswitch, when SL 216 is asserted (SL 216 is high), the logic gates lack a complete conduction path (due to headswitch 212 turning off and isolating VDD 206 from the logic gates 210), and, thus, the drain of leakage current from VDD 206 by the LVT logic gates 210 is substantially eliminated.

Circuit 500 also includes a NMOS pulldown transistor 510 with its gate terminal electrically connected to SL 216. When the pulldown transistor 510 is on, the output 218 is pulled to the reference voltage GND 208. Specifically, when the logic gates enter a sleep mode by asserting SL 216 (SL 216 is high), the NMOS pulldown transistor is turned on, thus providing a conductive path between output 218 and GND 208. As such, the output 218 is pulled down to a known, non-floating voltage level.

In sum, the embodiment of FIG. 5 may be advantageous over a standard MTCMOS circuit, such as circuit 100, for example, in several respects. First, circuit 500 does not have a footswitch and therefore requires less circuit area. Second, pulldown transistor 510 ensures that output 218 does not float when SL 216 is asserted and the circuit 500 is in a sleep mode, thus preventing crowbar current from being drawn by components connected to output 218.

FIG. 6 is a schematic of a circuit 600 illustrating a CMOS inverter connected to VDD 206 via the headswitch 212 and having an output electrically connected to the pulldown transistor 510. As shown in FIG. 6, LVT logic gates 210 comprise a CMOS inverter, which comprises the LVT PMOS transistor 410 and the LVT NMOS transistor 420 both receiving input signal 230. As discussed above, when the input 230 is low, the LVT PMOS transistor 410 creates a conduction path between the VDD 206 and the output 430 and when the input 230 is high, the LVT NMOS transistor 420 creates a conduction path between the GND 208 and the output 430

As noted above, the LVT logic gates 210 are electrically connected to a headswitch 212 for switching the logic gates between active and sleep modes. In brief, when SL 216 is asserted (SL 216 is high), the headswitch 212 is off, isolating VDD 206 from the logic gates 210, and the LVT logic gates 210 are in the sleep mode. Conversely, when SL 216 is de-asserted (SL 216 is low), the headswitch 212 is on, electrically connecting the VDD 206 with the logic gates 210, and the LVT logic gates 210 are in the active mode. The use of only the headswitch 212 may require decreased circuit area compared to a system employing both a headswitch and a footswitch.

The output 610, which is the inverse of input 230, is additionally electrically connected to the pulldown transistor 510 to prevent the output 610 from floating when the LVT logic gates 210 are in the sleep mode. The operation of the pulldown transistor 510 is the same as described above with respect to FIG. 5. In brief, when SL 216 is asserted (SL 216 is high) the LVT logic gates 210 enter a sleep mode and the pulldown transistor 510 turns on, thus providing an electrical connection between the output 610 and GND 208 and pulling the output 610 to GND 208. Because the output 610 is prevented from floating during the sleep mode, additional logic gates, such as the inverter 450, for example, may be electrically connected to the output 610 without the risk of unwanted crowbar current flowing through the inverter 450.

Those of skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is electrically connected to the processor such the processor can read information from, and write information to, the storage medium. In the alternative, the storage medium may be integral to the processor. The processor and the storage medium may reside in an ASIC. The ASIC may reside in a mobile station, base station, or base station controller. In the alternative, the processor and the storage medium may reside as discrete components in a mobile station, base station, or base station controller.

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

What is claimed is:

1. An integrated circuit comprising:
a logic gate comprising a reference terminal and an output terminal;
a footswitch having a first terminal electrically connected to the reference terminal and a second terminal electrically connected to a reference signal; and
a transistor electrically connected to the output terminal for adjusting a voltage level on the output terminal to a known voltage level when the footswitch is off.

2. The integrated circuit of claim 1, wherein the transistor is a pullup transistor connected to the output for increasing a voltage level on the output terminal to a known voltage level.

3. The integrated circuit of claim 1, wherein the transistor is a pulldown transistor connected to the output for decreasing a voltage level on the output terminal to a known voltage level.

4. The integrated circuit of claim 2, wherein the footswitch comprises a NMOS transistor and the pullup transistor comprises a PMOS transistor.

5. The integrated circuit of claim 4, wherein a threshold voltage of the NMOS transistor is higher than a threshold voltage of the logic gate.

6. The integrated circuit of claim 4, further comprising:
a sleep signal electrically connected to the footswitch and the pullup transistor for controlling the footswitch and the pullup transistor, wherein when the sleep signal is asserted the footswitch is turned off and the pullup transistor is turned on.

7. The integrated circuit of claim 1, further comprising a headswitch comprising a first terminal electrically connected to a voltage terminal of the logic gate and a second terminal electrically connected to a voltage source.

8. The integrated circuit of claim 1, wherein the logic gate comprises a CMOS inverter.

9. An integrated circuit comprising:
a logic gate comprising a voltage terminal and an output terminal;
a headswitch comprising a first terminal electrically connected to the voltage terminal and a second terminal electrically connected to a voltage source; and
a transistor electrically connected to the output terminal for adjusting a voltage level on the output terminal to a known voltage level when the headswitch is off.

10. The integrated circuit of claim 9, wherein the transistor is a pullup transistor connected to the output terminal for increasing a voltage level on the output terminal to a known voltage level.

11. The integrated circuit of claim 9, wherein the transistor is a pulldown transistor connected to the output terminal for decreasing a voltage level on the output terminal to a known voltage level.

12. The integrated circuit of claim 11, wherein the headswitch comprises a PMOS transistor and the pulldown transistor comprises a NMOS transistor.

13. The integrated circuit of claim 12, wherein a threshold voltage of the NMOS transistor is higher than a threshold voltage of the logic gate.

14. The integrated circuit of claim 12, further comprising:
a sleep signal electrically connected to the headswitch and the pulldown transistor for turning the headswitch and the pulldown transistor on and off, wherein when the sleep signal is asserted the headswitch is turned off and the pulldown transistor is turned on.

15. The integrated circuit of claim 9, further comprising a footswitch comprising a first terminal electrically connected to a reference terminal and a second terminal electrically connected to a reference signal.

16. A Multi-Threshold CMOS (MTCMOS) circuit comprising a sleep mode and an active mode, and comprising an output terminal electrically connected to a pullup transistor, wherein the pullup transistor is configured to maintain a known voltage level on the output terminal while the MTCMOS circuit is in the sleep mode.

17. The MTCMOS circuit of claim 16, wherein the footswitch comprises a NMOS transistor and the pullup transistor comprises a PMOS transistor.

18. An electronic device comprising an integrated circuit, the integrated circuit comprising:
a logic gate comprising an output terminal;
a pullup transistor electrically connected to the output terminal;
means for isolating the logic gate from a reference voltage; and
means for adjusting a voltage level on the output terminal to a known voltage level, wherein the acts of isolating and adjusting occur substantially simultaneously.

19. The electronic device of claim 18, wherein the logic gate comprises a CMOS logic gate.

20. The electronic device of claim 18, wherein the electronic device is a wireless telephone or a pager.

21. A method of preventing an output of a logic gate from floating when the logic gate is in a sleep mode, the method comprising:
providing a footswitch electrically connected to a reference terminal of the logic gate, wherein the sleep mode occurs when the footswitch is off;
proving a pullup transistor electrically connected to an output terminal of the logic gate; and
activating the pullup transistor when the logic gate is in a sleep mode.

22. The method of claim 21, wherein the logic gate comprises a CMOS inverter.

23. The method of claim 21, wherein the footswitch comprises a NMOS transistor and the pullup transistor comprises a PMOS transistor.

24. A method of preventing a voltage level on an output terminal of a logic gate from floating, the method comprising:
providing a pullup transistor electrically connected to the output terminal;
deactivating a footswitch connected to the logic gate, wherein the deactivating isolates the logic gate from a reference voltage; and
activating the pullup transistor so that the voltage level on the output terminal is adjusted to a known voltage level, wherein the acts of activating and deactivating occur substantially simultaneously.

25. The method of claim 24, further comprising:
deactivating a headswitch connected to the logic gate, wherein the deactivating isolates the logic gate from a voltage source.

26. A method of preventing a component electrically connected to an output terminal of a Multi-Threshold CMOS circuit from drawing crowbar current by activating a transistor electrically connected to the output terminal so that a voltage level on the output terminal is adjusted to about a known voltage level.

27. The method of claim 26, wherein the transistor is connected to a voltage source providing the known voltage level so that when the transistor is activated the known voltage level on the output terminal is substantially equal to the known voltage level.

28. The method of claim 26, wherein the transistor is connected to a reference voltage so that when the transistor is activated a voltage level on the output terminal is substantially equal to a voltage level of the reference voltage.
